(19) United States
(12) Patent Application Publication
(10) Pub. No.: US 2026/0092713 A1
(43) Pub. Date: Apr. 2, 2026

(54) LOAD CONTROL DEVICE FOR CONTROLLING AN ELECTRICAL LOAD IN RESPONSE TO SENSE AN ENVIRONMENTAL CHARACTERISTIC

(71) Applicant: Lutron Technology Company LLC, Coopersburg, PA (US)

(72) Inventors: Matthew Philip McDonald, Phoenixville, PA (US); Justin McIntire, Coopersburg, PA (US); Andrés Alejandro Orta, Delray Beach, FL (US)

(73) Assignee: Lutron Technology Company LLC, Coopersburg, PA (US)

(21) Appl. No.: 19/339,847

(22) Filed: Sep. 25, 2025

Related U.S. Application Data
(60) Provisional application No. 63/698,776, filed on Sep. 25, 2024.

(51) Int. Cl. F24F 11/00; F24F 11/52; F24F 11/88; G01D 11/24; G05B 11/01; H05K 5/00

(52) U.S. Cl. CPC F24F 11/0008; F24F 11/52; F24F 11/88; G01D 11/245; G05B 11/017; H05K 5/006; G05B 2219/37375

(57) ABSTRACT

A control device may be configured to control an electrical load (e.g., an exhaust fan) for controlling an environmental characteristic (e.g., a humidity level) in a space. The control device an actuator received in an opening in a front surface of a bezel, which may comprise first and second side portions on each side of the actuator. The control device may comprise an environmental sensing circuit for sensing the environmental characteristic in the space, and a control circuit configured to control the electrical load in response to actuations of the actuator and/or the environmental sensing circuit. The bezel may comprise a ventilation portion on the first or second side portion of the front surface. The ventilation portion may have apertures extending from the front surface to a cavity in the bezel. The environmental sensing circuit may be configured to receive air from outside of the bezel via the cavity.

### CROSS-REFERENCE TO RELATED APPLICATIONS

This application claims benefit of Provisional U.S. Patent Application No. 63/698,776, filed on Sep. 25, 2024, the entire disclosure of which are hereby incorporated by reference herein in their entirety.

### BACKGROUND

A user environment, such as a residence or an office building for example, may be configured using various types of load control systems. A lighting control system may be used to control the lighting loads in the user environment. A motorized window treatment control system may be used to control the natural light provided to the user environment. A heating, ventilation, and air-conditioning (HVAC) system may be used to control the temperature in the user environment. Each load control system may include various control devices, including control-source devices and control-target devices. The control-target devices may receive digital messages, which may include load control data, for controlling an electrical load from one or more of the control-source devices. The control-target devices may be configured to directly control an electrical load. The control-source devices may be configured to indirectly control the electrical load via the control-target device. Examples of control-target devices may include lighting control devices (e.g., a dimmer switch, an electronic switch, a ballast, or a light-emitting diode (LED) driver), a motor control device (e.g., for a ceiling fan or exhaust fan), a motorized window treatment, a temperature control device (e.g., a thermostat), an AC plug-in load control device, and/or the like. Examples of control-source devices may include remote-control devices, occupancy sensors, daylight sensors, temperature sensors, and/or the like.

### SUMMARY

As described herein, a control device may be configured to control an electrical load (e.g., such as an exhaust fan) for controlling an environmental characteristic (e.g., a humidity level) in a space around the control device. The control device may comprise a bezel comprising an opening in a front surface of the bezel and a control actuator received in the opening. The front surface of the bezel may comprise a first side portion on a left side of the control actuator and a second side portion on a right side of the control actuator. The control device may further comprise an environmental sensing circuit configured to sense the environmental characteristic in the space around the control device, and a control circuit configured to control the electrical load in response to actuations of the control actuator and in response to the environmental sensing circuit. The bezel may comprise a ventilation portion on at least one of the left side portion or the right side portion of the front surface of the bezel. The ventilation portion may comprise a plurality of apertures extending through the bezel from the front surface of the bezel to an interior surface of the bezel that is opposite the front surface of the bezel. The bezel may define a cavity located proximate the ventilation portion, where the interior surface of the bezel may define at least a portion of a boundary of the cavity. The environmental sensing circuit may be configured to receive air from outside of the bezel via the ventilation portion and the cavity in the bezel.

A motor control device for controlling a motor load is also disclosed herein. The motor control device may comprise a bezel comprising an opening in a front surface of the bezel, a control actuator received in the opening in the front surface of the bezel, where the front surface of the bezel comprises a first side portion on a left side of the control actuator and a second side portion on a right side of the control actuator. The motor control device may also comprise a humidity sensor circuit configured to sense an environmental characteristic in a space around the control device, and a control circuit configured to control the motor load in response to actuations of the control actuator and in response to the humidity sensor circuit in order to control a humidity level in the space in which the control device is located. The bezel may comprises a ventilation portion on at least one of the left side portion or the right side portion of the front surface of the bezel. The ventilation portion may comprise a plurality of apertures extending through the bezel from the front surface of the bezel to an interior surface of the bezel, the interior surface being opposite the front surface of the bezel. The bezel may further define a cavity located proximate the ventilation portion, where the interior surface of the bezel may define at least a portion of a boundary of the cavity. The humidity sensor circuit may be configured to receive air from outside of the bezel via the ventilation portion and the cavity in the bezel.

In addition, a control device for controlling an electrical load, may comprise a carrier configured to be mounted to an electrical wallbox, a bezel attached to the carrier to form a volume and comprising an opening in a front surface of the bezel, a control actuator received in the opening in the front surface of the bezel, a first printed circuit board supported by the carrier, a second printed circuit board supported by the carrier at a rear surface of the carrier, an environmental sensing circuit mounted to the second printed circuit board and received within a window in the carrier, and a control circuit mounted to the first printed circuit board electrically coupled to the environmental sensing circuit. The environmental sensing circuit may be configured to sense an environmental characteristic in a space around the control device. The control circuit may be configured to control the electrical load in response to actuations of the control actuator and in response to the environmental sensing circuit. The bezel, the carrier, and the second printed circuit board may form a volume in which the environmental sensing circuit is located. The bezel may comprise a ventilation portion having a plurality of apertures extending through the bezel to allow the environmental sensing circuit to receive air from outside of the bezel via the ventilation portion in the bezel.

### BRIEF DESCRIPTION OF THE DRAWINGS

FIG. 1 is a diagram of an example load control system for controlling the operation of an electrical device, such as a ceiling fan.

FIG. 2 is a perspective view of an example control device (e.g., a load control device, such as a humidity control device and/or a motor control device) for controlling an electrical load, such as an exhaust fan, to control a humidity level in a space in which the control device is located.

FIG. 3 is a front view of the control device of FIG. 2 with a faceplate removed.

FIG. 4 is a right-side cross-section view of the control device of FIG. 2.

FIG. 5 is a top cross-section view of the control device of FIG. 2.

FIG. 6 is an enlarged partial view of the top cross-section view of FIG. 5.

FIG. 7 is a front exploded view of the control device of FIG. 2.

FIG. 8 is a rear exploded view of the control device of FIG. 2.

FIG. 9 is an enlarged rear perspective view of a bezel and an actuator of the control device of FIG. 2.

FIG. 10 is a simplified block diagram of an example of a load control device that may be deployed as, for example, the control device of FIG. 2.

### DETAILED DESCRIPTION

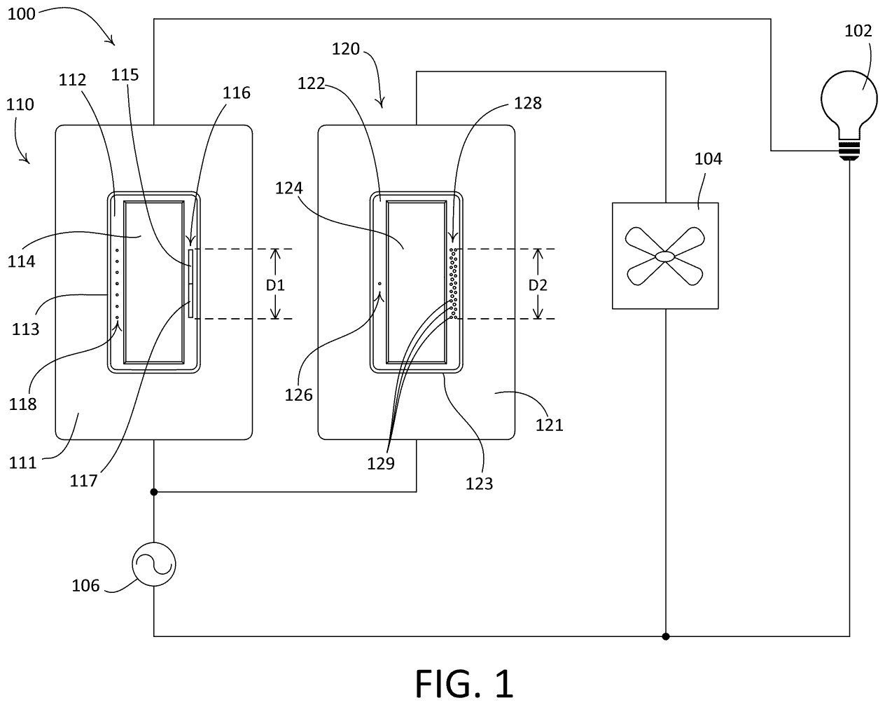

FIG. 1 is a diagram of an example load control system 100 for controlling the operation of one or more electrical devices. The load control system 100 may comprise a first load control device, such as a lighting control device 110 (e.g., an electronic switch and/or a dimmer switch) for controlling a lighting load 102, and a second load control device, such as a motor control device 120 for controlling a motor load, such as an exhaust fan 104. For example, the lighting load 102 and the exhaust fan 104 may be installed in a space, such as a bathroom, in which the lighting control device 110 may control the lighting load 102 to control a light level in the space and the motor control device 120 may control the exhaust fan 104 to control a humidity level in the space. The lighting control device 110 and the motor control device 120 may each be, for example, wall-mounted load control devices. In some examples, the lighting control device 110 and the motor control device 120 may be installed in close proximity to each other, for example, in the same electrical wallbox (e.g., in a multi-gang installation). In some examples, the lighting load 102 and the exhaust fan 104 may be separate fixtures, while in other examples the lighting load 102 and the exhaust fan 104 may be combined into a common (e.g., one) fixture.

The lighting control device 110 may be configured to be electrically coupled in series between a power source 106, such as an alternating-current (AC) power source or a direct-current (DC) power source, and the lighting load 102. The lighting control device 110 may be configured to turn the lighting load 102 on and off, and/or to control an amount of power delivered from the power source 106 to the lighting load 102 to adjust an intensity level LINT of the lighting load 102. The lighting control device 110 may comprise a bezel 112 configured to be received in an opening 113 of a faceplate 111 (e.g., which may be installed on the lighting control device 110).

The lighting control device 110 may comprise a control actuator 114 (e.g., an on/off actuator and/or a toggle actuator) and an intensity adjustment actuator 116, which may both be arranged on the bezel 112. For example, the control actuator 114 may be centered (e.g., substantially centered) within on the bezel 112. The lighting control device 110 may be configured to turn the lighting load 102 on and off in response to actuations of the control actuator 114. The intensity adjustment actuator 116 may be located on one side of the bezel 112 (e.g., on the right side as shown in FIG. 1) between the control actuator 114 and the opening 113 of the faceplate 111. For example, the intensity adjustment actuator 116 may extend for a distance D1 along the side of the bezel 112. The intensity adjustment actuator 116 may comprise, for example, a rocker switch having an upper portion 115 and a lower portion 117. The lighting control device 110 may be configured to increase and decrease the intensity level LINT of the lighting load 102 in response to actuations of the upper portion 115 and the lower portion 117 of the intensity adjustment actuator 116, respectively.

The lighting control device 110 may further comprise a plurality of visible indicators 118, which may also be arranged on the bezel 112. The plurality of visible indicators 118 may be located on the opposite side of the bezel 112 as the intensity adjustment actuator 116 (e.g., on the left side as shown in FIG. 1) between the control actuator 114 and the opening 113 of the faceplate 111. For example, the plurality of visible indicators 118 may be arranged in a linear array and may be illuminated by one or more respective light sources (e.g., light-emitting diodes) located behind the bezel 112 within the lighting control device 110. The lighting control device 110 may be configured to illuminate the plurality of visible indicators 118 to indicate the intensity level LINT of the lighting load 102 (e.g., to which the lighting control device 110 is controlling the lighting load 102).

The motor control device 120 may be configured to be electrically coupled in series between the power source 106 and the exhaust fan 104 to control power delivered from the power source 106 to the exhaust fan 104. The motor control device 120 may be configured to turn the exhaust fan 104 on and off. In some examples, the motor control device 120 may also be configured to control a rotational speed of the exhaust fan 104. The motor control device 120 may comprise a bezel 122 configured to be received in an opening 123 of a faceplate 121 (e.g., which may be installed on the motor control device 120). The motor control device 120 may comprise a control actuator 124 (e.g., an on/off actuator and/or a toggle actuator), which may be arranged on the bezel 122. For example, the control actuator 124 may be centered (e.g., substantially centered) within the bezel 122. The motor control device 120 may be configured to turn the exhaust fan 104 on and off in response to actuations of the control actuator 124. The motor control device 120 may comprise a visible indicator 126 on one side of the bezel 122 (e.g., on the left side as shown in FIG. 1) between the control actuator 124 and the opening 123 of the faceplate 121. For example, the visible indicator 126 may be illuminated by a light source (e.g., a light-emitting diode) located behind the bezel 122 within the motor control device 120. The motor control device 120 may be configured to illuminate the visible indicator 126 to indicate a status and/or a mode of the motor control device 120. For example, the motor control device 120 may be configured to illuminate the visible indicator 126 when the exhaust fan 104 is on and not to illuminate the visible indicator 126 or illuminate the visible indicator 126 to a dim level when the exhaust fan 104 is off.

The motor control device 120 may also be configured to control (e.g., automatically control) the exhaust fan 104 in response to one or more environmental characteristics (e.g., a humidity level and/or an ambient temperature) in the space in which the motor control device 120 located and/or is installed. For example, the motor control device 120 may comprise an internal sensor (not shown) located behind the bezel 122 for measuring the humidity level in the space around the motor control device 120. The motor control device 120 (e.g., the bezel 122) may comprise a ventilation portion 128 configured to allow air from outside of the motor control device 120 (e.g., from the space around the exterior of the motor control device 120) to enter the motor control device 120 (e.g., the interior of the motor control device 120) to be measured by the internal sensor of the motor control device 120. For example, the ventilation portion 128 may comprise a plurality of apertures 129 extending through the bezel 122 from outside of the motor control device 120 to a cavity inside of the motor control device 120. The internal sensor may be located in the cavity proximate to the ventilation portion 128 (e.g., as will be described in greater detail below). The plurality of apertures 129 of the ventilation portion 128 may be located within an area on the opposite side of the bezel 122 as the visible indicator 126 (e.g., on the right side as shown in FIG. 1) between the control actuator 114 and the opening 113 of the faceplate 121. The ventilation portion 128 may extend for a distance D2 along the side of the bezel 122. The motor control device 120 may be configured to control (e.g., automatically control) the exhaust fan 104 to turn the exhaust fan 104 on and off to thus control a humidity level in the space in which the motor control device 120 is located. One will appreciate that motor control device 120 as shown in FIG. 1 is an example and other variations are possible. For example, the visible indicator 126 may be omitted or located on other areas of bezel 122. The ventilation portion 128 may be located on other areas of bezel 122, such as on the left side, etc. The apertures 129 of the ventilation portion 128 may have other configurations including, for example, have other patterns, be slats rather than or in addition to holes, etc.

Since the lighting control device 110 and the motor control device 120 may be installed adjacent to each other, the lighting control device 110 and the motor control device 120 may be designed to have consistent aesthetic appearances. For example, the visible indicator 126 of the motor control device 120 may be located on the same side of the bezel 122 as the side of the bezel 112 of the lighting control device 110 on which the plurality of visible indicators 118 are located (e.g., the left sides of the bezels 112, 122). In addition, the ventilation portion 128 of the lighting control device 120 may be located on the same side of the bezel 122 as the side of the bezel 112 of the lighting control device 110 on which the intensity adjustment actuator 126 is located (e.g., the right sides of the bezels 112, 122). Further, the distance D2 for which the ventilation portion 128 of the motor control device 120 extends along the side of the bezel 122 may be equal to or approximately equal to the distance D1 for which the intensity adjustment actuator 126 of the lighting control device 110 extends along the side of the bezel 112.

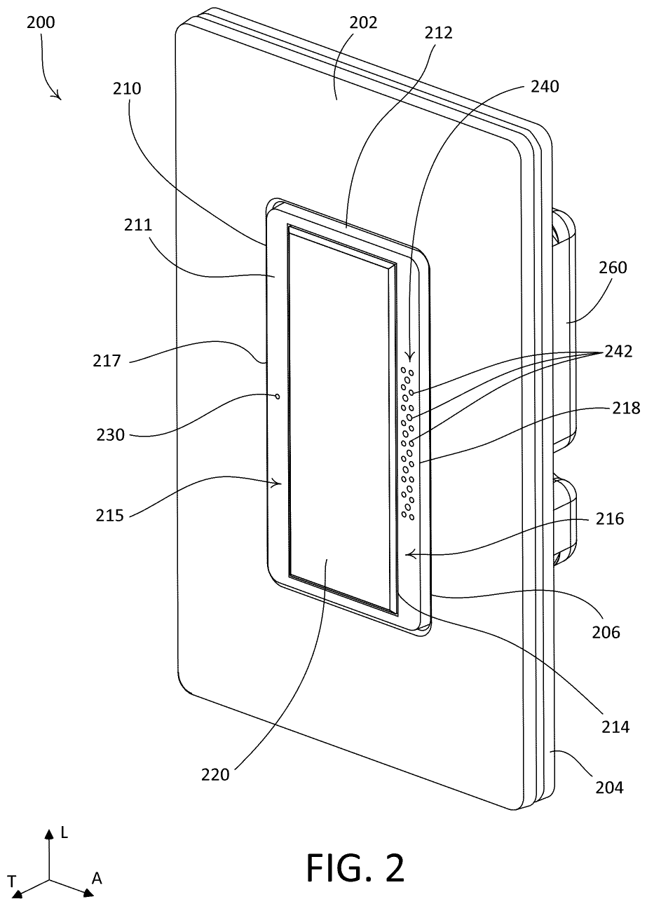

FIGS. 2-7 depict an example control device 200 (e.g., a load control device, such as a humidity control device and/or a motor control device) for controlling an electrical load, such as an exhaust fan (e.g., the exhaust fan 104), to control a humidity level in a space in which the control device 200 is located and/or installed. For example, the control device 200 may be deployed as the motor control device 120 of the load control system 100 shown in FIG. 1. The control device 200 may comprise, for example, a wall-mounted device configured to be mounted to an electrical wallbox. The control device 200 may be configured to be electrically coupled in series between a power source (e.g., the power source 106) and the exhaust fan for controlling power delivered from the power source to the exhaust fan, for example, to turn the exhaust fan on and off.

FIG. 2 is a perspective view of the control device 200 with an example a faceplate 202 and an adapter plate 204 mounted thereto. The faceplate 202 may be attached (e.g., clipped or snapped) to the adapter plate 204, which may be configured to be attached to the control device 200 (e.g., as will be described in greater detail below). For example, the faceplate 202 may comprise a designer-style faceplate defining an opening 206 having a standard size. Per standards set by the National Electrical Manufacturers Association (NEMA), the opening of a designer-style faceplate (e.g., the opening 206 of the faceplate 202) may have a length of 2.630″ and a width of 1.310″ (NEMA Standards Publication No. WD6, 2001, p. 5). In some examples, the control device 200 may have a single-piece faceplate (e.g., that does not include an adapter plate) mounted thereto.

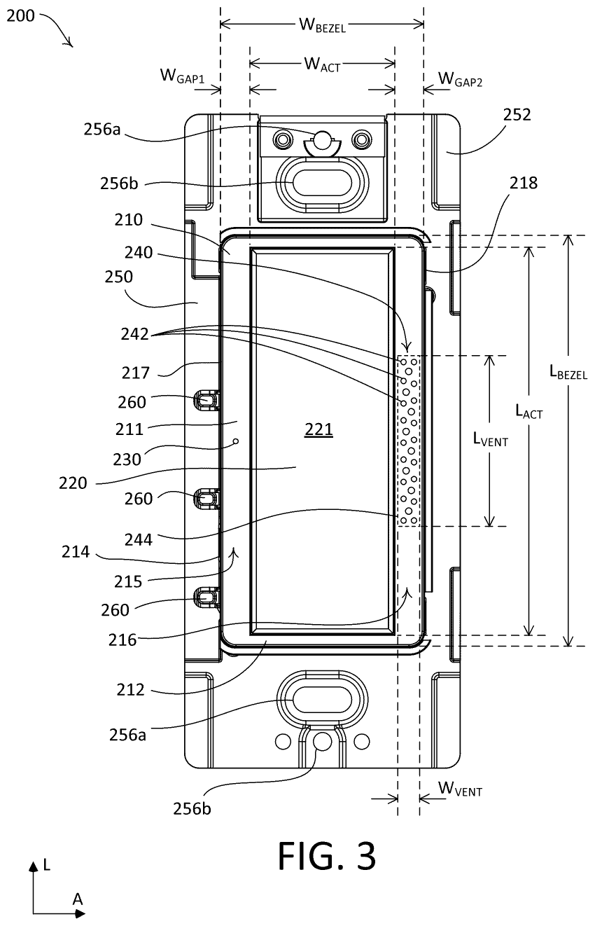

FIG. 3 is a front view of the control device 200 with the faceplate 202 and the adapter plate 204 removed. The control device 200 may comprise a bezel 210 that is configured to be received in the opening 206 of the faceplate 202 (e.g., when the faceplate 202 and the adapter plate 204 are mounted to the control device 200). The bezel 210 may comprise a body 212 having a front surface 211 that may be located in a plate that extends in a longitudinal direction L and a lateral direction A. The front surface 211 of the bezel 210 may be positioned within the opening 206 of the faceplate 202 when the faceplate 202 is mounted to the control device 200. The bezel 210 (e.g., the front surface 211) may be characterized by a length L_{BEZEL} (e.g., approximately 2.60 inches) in the longitudinal direction L and a width W_{BEZEL} (e.g., approximately 1.26 inches) in the lateral direction A. The front surface 211 of the bezel 210 may be characterized by an area A_{BEZEL} (e.g., in a plane that extends in the longitudinal direction L and a lateral direction A) that may be defined by the length L_{BEZEL} and the width W_{BEZEL} (e.g., A_{BEZEL}=L_{BEZEL}·W_{BEZEL}).

The control device 200 may further comprise a control actuator 220 (e.g., an on/off actuator and/or a toggle actuator), which may be received in an opening 214 in the front surface 211 of the bezel 210. The control actuator 220 may have a front surface 221 that may be located in a platen that extends in the longitudinal direction L and the lateral direction A. The control device 200 may be configured to turn the exhaust fan on and off in response to actuations of the control actuator 220. For example, the control actuator 220 may be pushed into the bezel 210 (e.g., further into the opening 214 in the bezel 210) for causing the control device 200 to alternately turn on and turn off the exhaust fan upon each actuation of the control actuator 220 (e.g., the control actuator 220 may comprise a pushbutton). The control actuator 220 may be arranged on the front surface 211 of the bezel 210, for example, such that the control actuator 220 is centered (e.g., substantially centered) within the front surface 211 of the bezel 122. For example, the control actuator 220 may bisect the front surface 211 of the bezel 210, such that the front surface 211 of the bezel 210 may comprise a first side portion 215 (e.g., a left side portion) between a left side edge 217 of the bezel 210 and the opening 214, and a second side portion 216 (e.g., a right side portion) between the opening 214 and a right side edge 218 of the bezel 210.

The control actuator 220 may be characterized by a length L_{ACT} (e.g., approximately 2.44 inches) in the longitudinal direction L and a width W_{ACT} (e.g., approximately 0.90 inches) in the lateral direction A. For example, the control actuator 220 may extend for almost all of, or substantially all of, the length L_{BEZEL} of the bezel 210 (e.g., more than approximately 90% of the length L_{BEZEL} of the bezel 210). The front surface 221 of the control actuator 220 may be characterized by an area A_{ACT} (e.g., in a plane that extends in the longitudinal direction L and a lateral direction A) that may be defined by the length L_{ACT} and the width W_{ACT} (e.g., A_{ACT}=L_{ACT}·W_{ACT}). An area A_{ACT} of the control actuator 220 (e.g., the opening 214 in the bezel 210) may occupy, for example, approximately 67% (e.g., approximately two-thirds) of the area A_{BEZEL} of the front surface 211 of the bezel 210 (e.g., in the plane of the front surface 211 of the bezel 210). The first and second side portions 215, 216 of the front surface 211 of the bezel 210 may be characterized by respective widths W_{GAP1}, W_{GAP2} in the lateral direction A. For example, the widths W_{GAP1}, W_{GAP2} of the first and second side portions 215, 216 of the front surface 211 may be equal or approximately equal (e.g., each approximately 0.17 inches).

The control device 200 (e.g., the bezel 210) may comprise a visible indicator 230, which may be located on, for example, the first side portion 215 of the front surface 211 of the bezel between the left side edge 217 of the bezel 210 and the opening 214 in which the control actuator 220 is located. For example, the visible indicator 230 may be illuminated to indicate a status and/or a mode of the control device 200. For example, the control device 200 may be configured to illuminate the visible indicator 230 when the exhaust fan is on and to not illuminate the visible indicator 230 or illuminate the visible indicator 230 to a dim level when the exhaust fan is off.

The control device 200 (e.g., the bezel 210) may further comprise a ventilation portion 240 configured to allow air from outside of the control device 200 (e.g., external to the control device) to enter the control device 200 (e.g., to enter an interior of the control device) to enable the control device 200 to sense one or more environmental characteristics (e.g., a humidity level and/or an ambient temperature) in the space in which the control device 200 is located and/or installed. The ventilation portion 240 may comprise a plurality of apertures 242 extending through the bezel 210 to allow air from outside of the control device 200 to enter the control device 200 (e.g., as will be described in greater detail below). The ventilation portion 240 may be located on, for example, the second side portion 216 of the front surface 211 of the bezel 210 between the right side edge 218 of the bezel 210 and the opening 214 in which the control actuator 220 is located. The plurality of apertures 242 of the ventilation portion 240 may be located within an area 244 (e.g., in a plane that extends in the longitudinal direction L and the lateral direction A) on the second side portion 216 of the front surface 211 of the bezel 214 (e.g., between the right side edge 218 of the bezel 210 and the opening 214 in which the control actuator 220 is located). For example, the area 244 in which the apertures 242 of the ventilation portion 240 may be located may be characterized by a length L_{VENT} (e.g., approximately 1.15 inches) in the longitudinal direction L and a width W_{VENT} (e.g., approximately 0.13 inches) in the lateral direction A. The ventilation portion 240 may extend for approximately one-half (e.g., approximately 54%) of the length L_{BEZEL} of the bezel 210 along the second side portion 216 of the front surface 211 of the bezel 210.

The control device 200 may be configured to control (e.g., automatically control) the exhaust fan in response to the sensed one or more environmental characteristics, for example, to control a humidity level L_{HUM} in the space in which the control device 200 is located and/or installed by turning the exhaust fan on and off. For example, the control device 200 may be configured to determine the humidity level L_{HUM} from the air from outside of the control device 200 that is received into the control device 200 via the ventilation portion 240. For example, the control device 200 may be configured to turn on the exhaust fan when the humidity level L_{HUM} exceeds a first threshold humidity L_{TH-H1} (e.g., a turn-on threshold humidity). The control device 200 may be configured to turn off the exhaust fan when the humidity level L_{HUM} drops below a second threshold humidity L_{TH-H2} (e.g., a turn-off threshold humidity), which may be less than the first threshold humidity level L_{TH-H1}. In addition, the control device 200 may be configured to turn off the exhaust fan after a timeout period T_{TIME-OUT} from when the control device 200 turned on (e.g., automatically turned on) the exhaust fan in response to the humidity level L_{HUM} determined by the control device 200.

The control device 200 may be configured to operate in one or more different operating modes, such as a humidity-control mode, an air-cycle mode, and a manual mode. When in the humidity-control mode, the control device 200 may be configured to control (e.g., automatically control) the exhaust fan in response to the humidity level L_{HUM} determined by the control device 200. For example, when in the humidity-control mode, the control device 200 may be configured to turn on the exhaust fan when the humidity level L_{HUM} exceeds the first threshold humidity L_{TH-H1}, and to turn off the exhaust fan when the humidity level L_{HUM} drops below the second threshold humidity L_{TH-H2} or after the timeout period T_{TIME-OUT} from when the control device 200 turned on the exhaust fan in response to the humidity level L_{HUM}. When in the air-cycle mode, the control device 200 may be configured to periodically control the exhaust fan (e.g., according to a time schedule). For example, when in the air-cycle mode, the control device 200 may be configured to turn on the exhaust fan for an air-cycle period TAIR-CYCLE (e.g., approximately 15 minutes) each hour. When in the manual mode, the control device 200 may be configured to turn on (e.g., only turn on) the exhaust fan in response to an actuation of the control actuator 220. In addition, when in the manual mode, the control device 200 may be configured to turn off the exhaust fan in response to an actuation of the control actuator 220 when the exhaust fan is on or after the timeout period T_{TIME-OUT} from when the control device 200 turned on the exhaust fan in response to an actuation of the control actuator 220. The control device 200 may not be configured to control (e.g., automatically control) the exhaust fan in response to the humidity level L_{HUM} determined by the control device 200 when in the air-cycle mode or the manual mode.

The control device 200 may comprise one or more programming actuators 260 (e.g., three programming actuators 260 as shown in FIG. 3). The programming actuators 260 may be exposed (e.g. to a user) when the faceplate 202 is removed from the control device 200 (e.g., detached from the adapter plate 204) and/or when the faceplate 202 and the adapter plate 204 are removed from the control device 200 (e.g., detached from the carrier 250). The control device 200 may configure one or more configuration settings and/or operational settings of the control device 200 in response to actuations of the programming actuators 260 by a user, for example. For example, the control device 200 may be configured to select one of the operating modes (e.g., the humidity-control mode, the air-cycle mode, and/or the manual mode) in which to operate in response to actuations of the programming actuators 260. In addition, the control device 200 may be configured to set a humidity sensitivity level to one of multiple levels (e.g., a low level, a medium level, and/or a high level) in response to actuations of the programming actuators 260. For example, the control device 200 may be configured to set the first threshold humidity L_{TH-H1} and/or the second threshold humidity L_{TH-H2} (e.g., to be used when operating in the humidity-control mode) based on the humidity sensitivity level that is set (e.g., one of the low level, the medium level, or the high level). Further, the control device 200 may be configured to set the timeout period T_{TIMEOUT} in response to actuations of the programming actuators 260. In some examples, the control device may be configured to set the air-cycle period T_{AIR-CYCLE} (e.g., for use in the air-cycle mode) in response to actuations of the programming actuators 260. In some examples, the control device 200 may comprise more or less programming actuators 260 (e.g., two programming actuators).

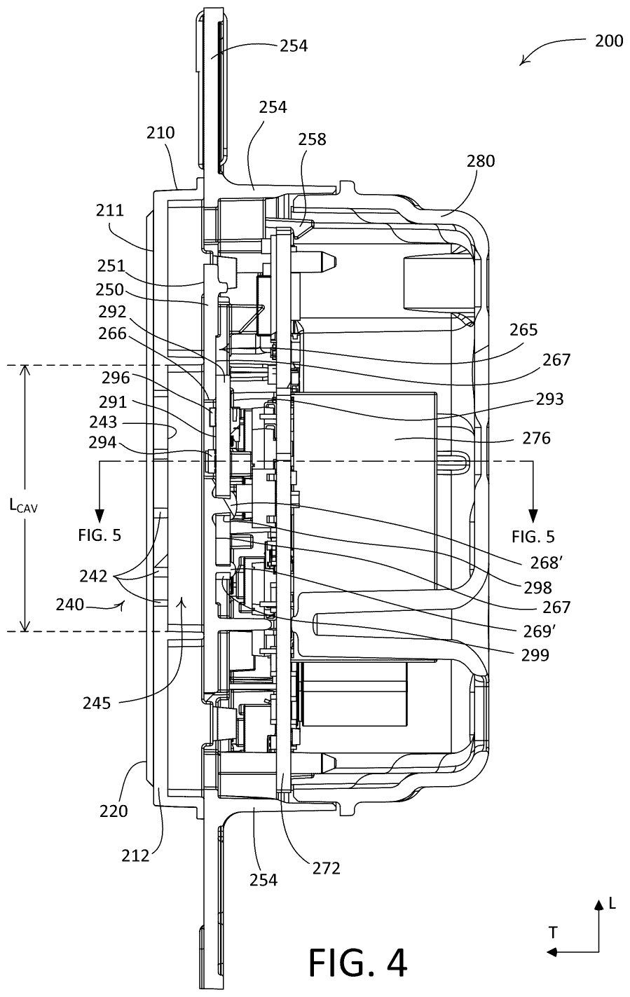

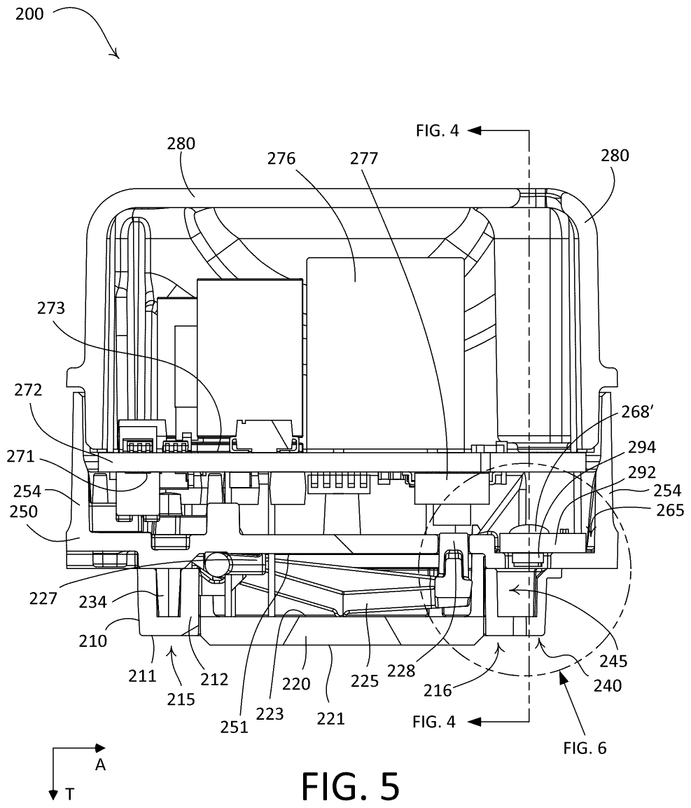

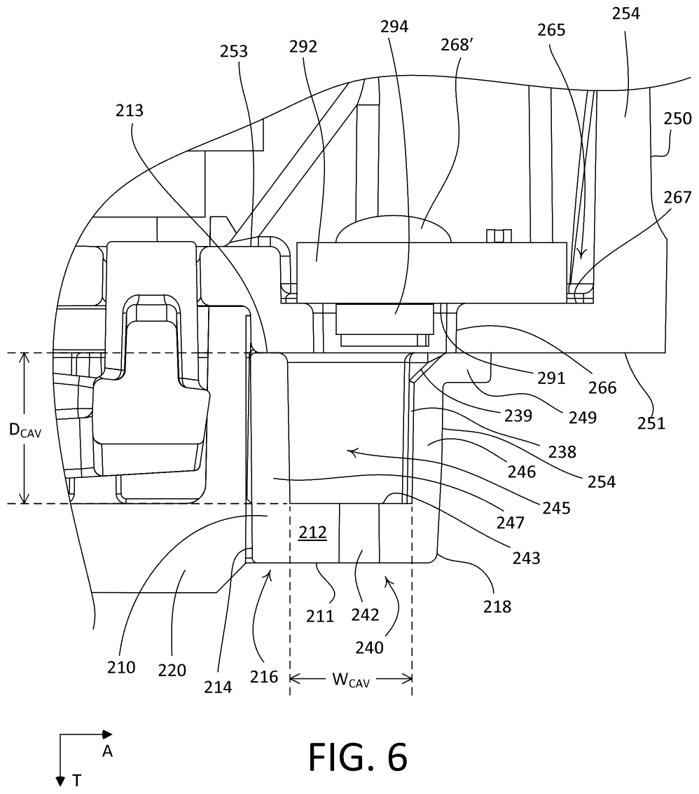

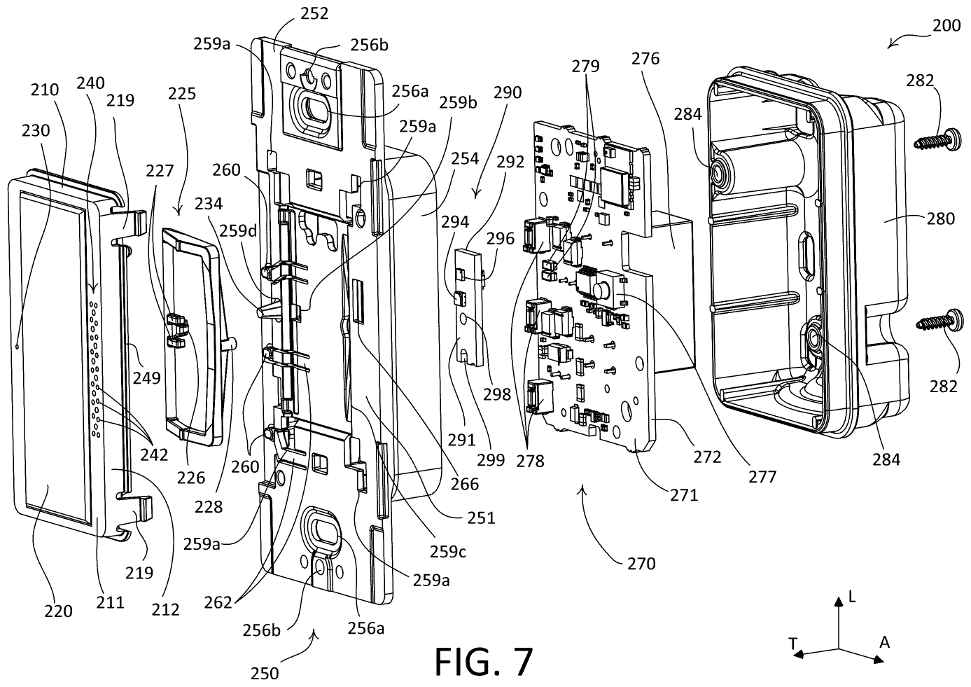

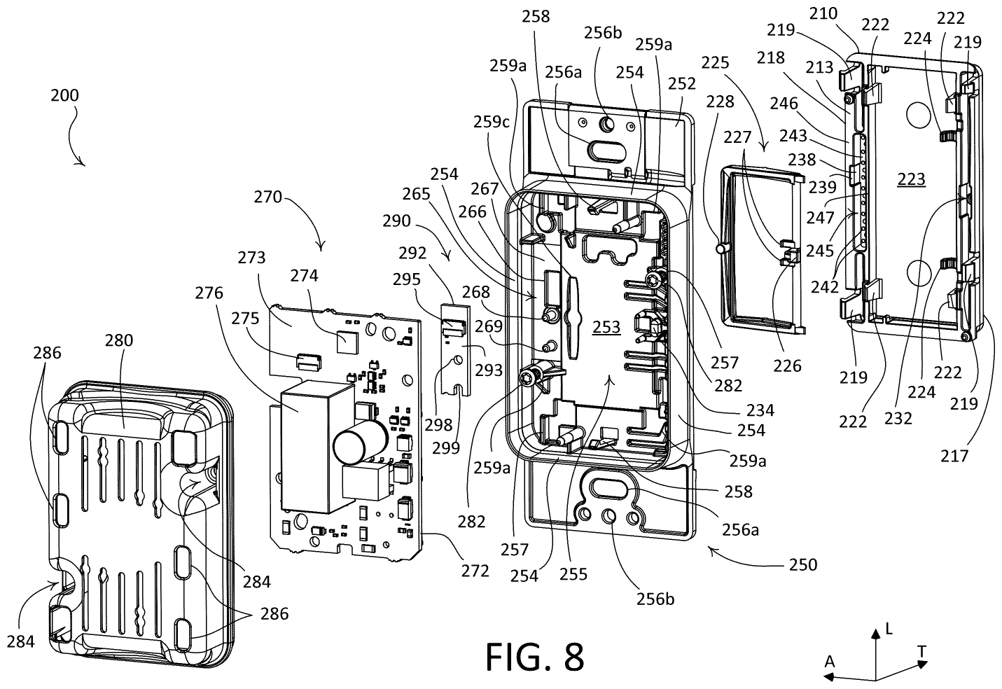

FIGS. 4-6 are cross-section views of the control device 200. FIG. 4 is a right-side cross-section view of the control device 200 taken through the line shown in FIG. 5. FIG. 5 is a top cross-section view of the control device 200 taken through the line shown in FIG. 4. FIG. 6 is an enlarged partial view of the top cross-section view of FIG. 5 (e.g., as illustrated by the circle in FIG. 5). FIG. 7 is a front exploded view and FIG. 8 is a rear exploded view of the control device 200.

The control device 200 may comprise a carrier 250 to which the bezel 220 may be attached (e.g., as shown in FIG. 3). The carrier 250 may comprise a yoke portion 252 (e.g., a front wall) and side walls 254 extending from the yoke portion (e.g., in the transverse direction T). The carrier 250 (e.g., the yoke portion 252) may comprise a front surface 251 and a rear surface 253 opposite the front surface 251. The yoke portion 252 (e.g., the rear surface 253) and the side walls 254 may define a cavity 255 of the carrier 250 (e.g., as shown in FIG. 8). The yoke portion 252 of the carrier 250 may comprise holes 256a for receiving fasteners (e.g., screws—not shown) for attaching (e.g., mounting) the control device 200 to an electrical wallbox, for example. In addition, the yoke portion 252 of the carrier 250 may also comprise holes 256b for receiving fasteners (e.g., screws—not shown) for attaching (e.g., mounting) the faceplate 202 and the adapter plate 204, for example, to the control device 200. For example, the fasteners may be received through the holes 256b of the carrier 250 and corresponding openings (not shown) of the adapter plate 204 for mounting the adapter plate 204 to the carrier 250, and the faceplate 202 may be attached to (e.g., clipped or snapped to) the adapter plate 204. One will appreciate other types or configurations of faceplates may be attached to the carrier 250 via the holes 256b and the respective fasteners.

The control device 200 may further comprise a first printed circuit board assembly 270 and an enclosure 280 (e.g., a rear enclosure). The first printed circuit board assembly 270 may comprise a first printed circuit board 272 (e.g., a main printed circuit board) to which electrical circuitry of the control device 200 is mounted. The first printed circuit board 272 may comprise a front side 271 and a rear side 273. The electrical circuitry of the control device 200 (e.g., the first printed circuit board assembly 270) may comprise a control circuit, such a processor 274 (e.g., a microprocessor), which may be mounted to the first printed circuit board 272 (e.g., to the rear side 273 of the first printed circuit board 272 as shown in FIG. 8). In addition, the electrical circuitry of the control device 200 (e.g., the first printed circuit board assembly 270) may also comprise a load control circuit, such as a relay 276 (e.g., a switching circuit), which may also be mounted to the first printed circuit board 272 (e.g., to the rear side 273 of the first printed circuit board 272). For example, the relay 276 may be configured to be electrically coupled between the power source and the exhaust fan for connecting the exhaust fan to and disconnecting the exhaust fan from the power source to turn the exhaust fan on and off, respectively. While not shown in the figures, the control device 200 may comprise one or more electrical conductors (e.g., wires) that may be electrically and mechanically coupled to the first printed circuit board 272 and may extend through openings 286 in the enclosure 280 (e.g., as shown in FIG. 8). The electrical conductors may be configured to electrically couple the control device 200 (e.g., the relay 276) to the power source and the exhaust fan.

The first printed circuit board 270 may be received within the cavity 255 of the carrier 250 (e.g., between the side walls 254) and supported by the carrier 252. For example, the carrier 250 may comprise clips 252 that may extend from the rear surface 253 of the yoke portion 252. The clips 258 may be configured to engage the rear side 273 of the first printed circuit board 270 to attach the first printed circuit board 270 to the carrier 250 within the cavity 255. The enclosure 280 may be configured to be attached to the carrier 250, thereby forming a first volume between the enclosure 280 and the carrier 250 (e.g., the rear surface of the yoke portion 252 of the carrier 250). The first printed circuit board 272 of the first printed circuit board assembly 270 may be housed within the first volume (e.g., captured between the enclosure 280 and the carrier 250). The control device 200 may comprise fasteners 282 (e.g., screws) that may be received through respective openings 284 in the enclosure 280 and respective openings 257 (FIG. 8) in the carrier 250 to secure the enclosure 280 to the carrier 250 (e.g., to the rear surface 253 of the carrier 250). For example, the openings 257 of the carrier 250 may be threaded openings (e.g., for receiving the fasteners 282). Note that the fasteners 282 are shown partially inserted into the openings 257 in the carrier 250 in FIG. 8.

The bezel 210 may be configured to be attached (e.g., clipped or snapped) to the carrier 250 (e.g., to the front surface 251 of the carrier 250). The bezel 210 may comprise clips 219 (e.g., four clips) that extend from a rear surface 213 of the body 212 of the bezel 210. The clips 219 of the bezel 210 may extend through openings 258a in the carrier 250 when the bezel 210 is attached to the carrier 250. The clips 219 may be configured to engage the rear surface 253 of the carrier 250 to attach the bezel 210 to the carrier 250 and hold the bezel 210 against a front surface 251 of the carrier 250. The control actuator 220 may comprise clips 222 (e.g., four clips) that extend from a rear surface 223 of the control actuator 220 (e.g., as shown in FIG. 8). The clips 222 of the control actuator 220 may be configured to engage the rear surface 213 of the bezel 210 to retain the control actuator 220 in the opening 214 of the bezel 210. The control actuator 220 may further comprise fingers 224 that extend from the rear surface 223 of the control actuator 220 and contact the front surface 251 of the carrier 250 when the bezel 210 is attached to the carrier 250.

The control device 200 may comprise an actuator support member 225 (e.g. a support frame), which may be located (e.g., captured) between the control actuator 220 (e.g., the rear surface 223 of the control actuator 220) and the carrier 250 (e.g., the front surface 251 of the carrier 250) when the bezel 210 is attached to the carrier 250. The actuator support member 225 may comprise a leg 226 that may be configured to extend through an opening 258b of the carrier 250 (FIG. 7). The actuator support member 225 may further comprise arms 227 that may rest against the front surface 251 of the carrier 250. The leg 226 and the arms 227 of the actuator support member 225 may be configured to hold the actuator support member 225 along the front surface 251 of the carrier 250 between the control actuator 220 and the carrier 250. The actuator support member 225 may further comprise a post 228 that extends from the actuator support member 225 through an opening 258c of carrier 250 towards the first printed circuit board assembly 270 (e.g., in a transverse direction T). For example, the post 228 may be located on the opposite side of the actuator support member 225 as the leg 226 and the arms 227.

The electrical circuitry of the control device 200 (e.g., the first printed circuit board assembly 270) may further comprise a tactile switch 277 mounted to the first printed circuit board 272 (e.g., to the front side 271 of the first printed circuit board 272). When the control actuator 220 is actuated (e.g., pressed into towards the carrier 250), the control actuator 220 may pivot (e.g., about the fingers 224 of the control actuator 220) and contact the actuator support member 225, such that the actuator support member 225 also pivots (e.g., about the leg 226 and/or the arms 227) and such that the post 228 of the actuator support member 225 (e.g., which extends through the opening 258c of the carrier 250) may actuate the tactile switch 277 mounted to the first printed circuit board 272. The actuator support member 225 may further operate as a return spring to return the control actuator 220 to an idle position (e.g., as shown in FIG. 2) after the actuation of the control actuator 220 is complete. The processor 274 may be configured to be responsive to the tactile switch 277 (e.g., to actuations of the tactile switch 277). The processor 274 may be further configured to control the relay 276 to open and close the relay 276 (e.g., to turn the exhaust fan on and off) in response to actuations of the control actuator 220.

The electrical circuitry of the control device 200 (e.g., the first printed circuit board assembly 270) may comprise one or more additional tactiles switches 278 (e.g., three tactiles switches) mounted to the first printed circuit board 272 (e.g., to the front side 271 of the first printed circuit board 272). The one or more tactiles switches 278 may be actuated in response to actuations of the one or more programming actuators 260 of the control device 200, respectively. For example, the programming actuators 260 may be formed as part of the carrier 250. Each of the programming actuators 260 may comprise a respective arm 262 (e.g., a spring arm) that may be cut into the front surface 251 of the carrier 250 and may be configured to flex. When one of the programming actuators 260 is pressed (e.g., in towards the first printed circuit board assembly 270 in the transverse direction T), the respective arm 262 may flex, such that the programming actuator 260 may actuate the respective tactile switch 278 on the first printed circuit board 272. When the actuation of the programing actuator 260 is complete (e.g., released by a user), the respective arm 262 may be configured to return the programming actuator 260 to an idle position. The processor 274 may be configured to be responsive to the tactile switches 278 (e.g., to actuations of one or more of the tactile switches 278).

The electrical circuitry of the control device 200 (e.g., the first printed circuit board assembly 270) may further comprise one or more light sources (e.g., two light sources), such as light-emitting diodes 279, mounted to the first printed circuit board 272. The light-emitting diodes 279 may be configured to illuminate the visible indicator 230 of the control device 200 (e.g. on the first side portion 215 of the front surface 211 of the bezel 210). The visible indicator 230 may be formed by an opening 232 (FIG. 8) that extends through the bezel 210. The control device 200 may comprise a light pipe 234 that extends from the light-emitting diodes 279 on the first printed circuit board 272 to the opening 232 in the bezel 210. For example, the light pipe 234 may extend through an opening 259d (FIG. 7) in the carrier 250. The light pipe 234 may be configured to conduct light from the light-emitting diodes 279 to illuminate the opening 232 in the bezel 210 to provide the visible indicator 230 on the first side portion 215 of the front surface 211 of the bezel 210. For example, a first one of the light-emitting diodes 279 may be configured to emit light at a first color (e.g., white) and a second one of the light-emitting diodes 279 may be configured to emit light at a second color (e.g., blue).

The processor 274 may be configured to control the light-emitting diodes 279 to illuminate the opening 232 in the bezel 210, for example, to illuminate the visible indicator 230 to indicate a status and/or a mode of the control device 200. For example, the processor 274 may be configured to control the light-emitting diodes 279 to illuminate the opening 232 in the bezel 210 to illuminate the visible indicator 230 when the exhaust fan is on and to not illuminate the visible indicator 230 or illuminate the visible indicator 230 to a dim level when the exhaust fan is off. In addition, the processor 274 may be configured to control the first one the light-emitting diodes 279 to illuminate the visible indicator 230 to the first color (e.g., white) when the processor 274 has turned on the exhaust fan in response to an actuation of the control actuator 220. Further, the processor 274 may be configured to control the second one the light-emitting diodes 279 to illuminate the visible indicator 230 to the second color (e.g., blue) when the processor 274 has turned on (e.g., automatically turned on) the exhaust fan in response to the sensed one or more environmental characteristics, for example, to control the humidity level in the space in which the control device 200 is located and/or installed.

The control device 200 may further comprise a second printed circuit board assembly 290. The second printed circuit board assembly 290 may comprise a second printed circuit board 292 (e.g., a daughter printed circuit board) to which one or more sensor circuits of the control device 200 may be mounted. For example, the second printed circuit board 292 may be arranged in a plane (e.g., a plane extending in the longitudinal direction L and the lateral direction A), which is parallel to a plane of the first printed circuit board 272. The second printed circuit board 292 may comprise a front side 291 that faces towards the bezel 210 (e.g., the rear surface 213 of the bezel 210) and a rear side 293 that is opposite the front side 291 and faces towards the first printed circuit board 272 (e.g., the front side 271 of the first printed circuit board 272). The electrical circuitry of the control device 200 (e.g., the second printed circuit board assembly 290) may comprise a first sensor circuit, such as an environmental sensing circuit 294 (e.g., a humidity sensing circuit and/or a temperature sensing circuit), mounted to the second printed circuit board 292 (e.g., to the first side 291 of the second printed circuit board 292). For example, the environmental sensing circuit 294 may comprise one or more integrated circuits (ICs). The environmental sensing circuit 294 may be configured to sense one or more environmental characteristics (e.g., a humidity level and/or an ambient temperature) in the space in which the control device 200 is located and/or installed. The ventilation portion 240 of the bezel 210 may be configured to allow air from outside of the control device 200 (e.g., from the space around the control device 200) to enter control device 200 to be measured by the environmental sensing circuit 294. The environmental sensing circuit 294 may be configured to generate one or more sense signals that are representative of the respective sensed environmental characteristics.

The processor 274 of the first printed circuit board assembly 270 may be electrically coupled to the environmental sensing circuit 294 and configured to receive the one or more sense signals generated by the environmental sensing circuit 294. The first printed circuit board assembly 270 may comprise a first connector 275 mounted to the first printed circuit board 272 (e.g., to the second side 273 of the first printed circuit board 272), and the second printed circuit board assembly 290 may comprise a second connector 295 mounted to the second printed circuit board 292 (e.g., to the second side 293 of the second printed circuit board 292). For example, the control device 200 may comprise a cable (e.g., a ribbon cable-not shown) that may extend between the first and second connectors 275, 295 for electrically coupling the first and second printed circuit boards 272, 292 to allow the environmental sensing circuit 294 to be electrically coupled to the processor 274. In some examples, the environmental sensing circuit 294 may be configured to transmit one or more messages (e.g., digital messages) including indications of the sensed environmental characteristics to the processor 274 via a communication bus (e.g., an I²C communication bus) formed by at least two electrical conductors of the cable. For example, the processor 274 may be configured to determine a humidity level L_{HUM} in in the space in which the control device 200 is located and/or installed.

The processor 274 may be configured to control the relay 276 in response to the one or more sense signals generated by the environmental sensing circuit 294, for example, to control (e.g., automatically control) the exhaust fan to turn the exhaust fan on and off to control the humidity level L_{HUM} in the space around the control device 200. For example, the processor 274 may be configured to turn on the exhaust fan when the humidity level L_{HUM} (e.g., as indicated by the one or more sense signals generated by the environmental sensing circuit 294) exceeds the first threshold humidity L_{TH-H1}. The processor 274 may be configured to turn off the exhaust fan when the humidity level L_{HUM} (e.g., as indicated by the one or more sense signals generated by the environmental sensing circuit 294) drops below the second threshold humidity L_{TH-H2}. In addition, the processor 274 may be configured to turn off the exhaust fan after a timeout period T_{TIME-OUT} from when the processor 274 turned on (e.g., automatically turned on) the exhaust fan in response to the one or more sense signals generated by the environmental sensing circuit 294.

The electrical circuitry of the control device 200 (e.g., the second printed circuit board assembly 290) may further comprise a second sensor circuit, such as photosensing circuit 296, mounted to the second printed circuit board 292 (e.g., to the first side 291 of the second printed circuit board 292). For example, the photosensing circuit 296 may comprise one or more integrated circuits (ICs). The photosensing circuit 296 may be configured to sense (e.g., measure) a light level L_{PS} (e.g., an ambient light level) in the space in which the control device 200 is located and/or installed. The photosensing circuit 296 may be configured to generate a sense signal that indicates and/or is representative of the light level L_{PS} in the space in which the control device 200 is located and/or installed (e.g., as measured by the photosensing circuit 296). The photosensing circuit 296 may be configured to receive light from outside of the control device 200 via one or more of the apertures 242 of the ventilation portion 240.

The processor 274 may be configured to receive the sense signal generated by the photosensing circuit 296 (e.g., via the cable connected between the first and second connectors 275, 295) and control the relay 276 in response to the sense signal received from the photosensing circuit 296. For example, the processor 274 may be configured to sample and process the sense signal generated by the photosensing circuit 296 to determine when the light level L_{PS} in the space in which the control device 200 is located and/or installed exceeds a light threshold L_{TH}, for example, to determine when a lighting load that is also installed in the space (e.g., the lighting load 102 controlled by the lighting control device 110) is turned on (e.g., which may provide an indication of when the space is occupied). The processor 274 may be configured to control the relay 276 to turn on (e.g., only automatically turn on) the exhaust fan in response to the one or more sense signals generated by the environmental sensing circuit 294 when the sense signal generated by the photosensing circuit 296 indicates that the space is occupied (e.g., when the light level L_{PS} exceeds the light threshold L_{TH}). The processor 274 may be configured to determine when the turn off the exhaust fan independent of the sense signal V_{PS} received from the photosensing circuit 296. In some example, the control device 200 may comprise an occupancy sensing circuit, such as a passive-infrared sensing circuit, for determining if the space is occupied (e.g., in place of or in addition to the photosensing circuit 296).

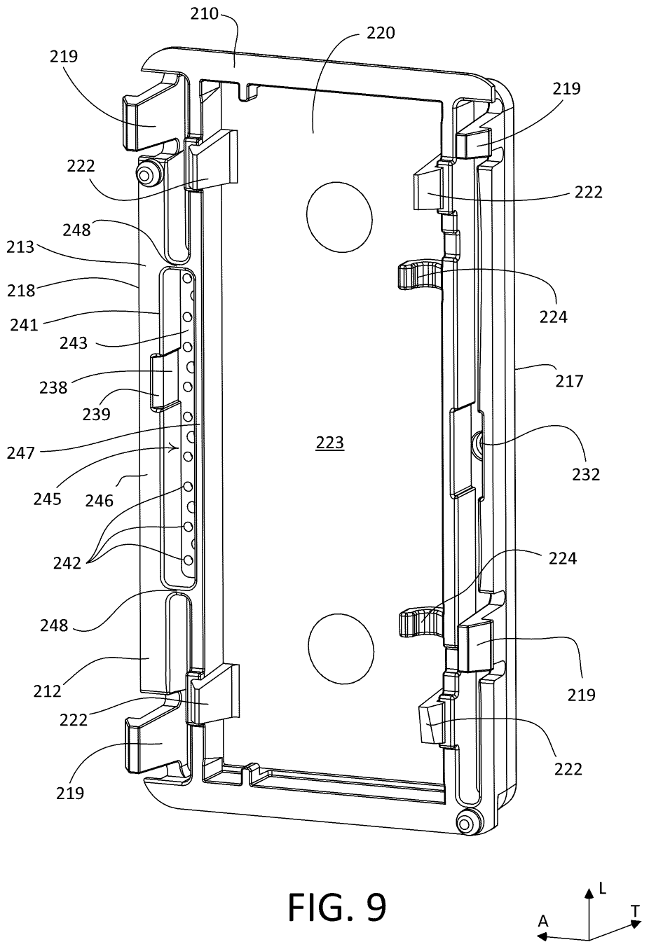

The second printed circuit board 292 may be located within (e.g., housed within) the control device 200 (e.g., within the first volume between the enclosure 280 and the carrier 250), such that the environmental sensing circuit 294 and the photosensing circuit 296 are located behind (e.g., immediately behind) and are directed towards the ventilation portion 240 on the bezel 210. For example, the bezel 210 may define a cavity 245 that is formed in the bezel 210 (e.g., on the rear surface 213 of the bezel 210) behind (e.g., immediately behind) the ventilation portion 240. FIG. 9 is an enlarged rear perspective view of the bezel 210 and the actuator 220 showing the cavity 245 in the bezel 210 in greater detail. The apertures 242 of the ventilation portion 240 may extend through the bezel 210 from the front surface 211 to an interior surface 243 of the body 212 of the bezel 211 within the cavity 245 (e.g., which is opposite the front surface 211 of the bezel 210). The interior surface 243 may define at least a portion of a boundary (e.g., a side) of the cavity 2245.

The cavity 245 may be open at the rear surface 213 of the bezel 210 (e.g., as shown in FIG. 9). For example, the cavity 245 may define an opening 241 (FIG. 9) at the rear surface 213 of the bezel 210 opposite the ventilation portion 240. The cavity 245 may be further formed by walls (e.g., at least an outer wall 246, an inner wall 247, and end walls 248 in the body 212 of the bezel 210 as described below) that extend in the transverse direction T between the opening 241 and the ventilation portion 240 (e.g. as shown in FIG. 9). The outer wall 246 of the body 212 of the bezel 210 (e.g., that defines the cavity 245) may be located between the cavity 245 and the right side edge 218 of the bezel 210. The inner wall 247 of the body 212 of the bezel 210 (e.g., that defines the cavity 245) may be located between the cavity 245 and the opening 214 (e.g., in which the control actuator 220 is located). The end walls 248 of the body 212 of the bezel 210 (e.g., that define the cavity 245) may be located (e.g., extend) between the outer walls 246 and the inner wall 247. The outer wall 246 may comprise a flange portion 249 where the bezel 210 contacts the front surface 251 of the carrier 250. The cavity 245 may have a cross-sectional area (e.g., in a plane that extends in the longitudinal direction L and the lateral direction A) that is, for example, approximately equal to the area 244 of the ventilation portion 240 on the front surface 211 of the bezel 210. For example, the cavity 245 may be characterized by a length L_{CAV} (e.g., approximately 1.15 inches) in the longitudinal direction L, a width W_{CAV} (e.g., approximately 0.13 inches) in the lateral direction A, and a depth D_{CAV} (e.g., approximately 0.15 inches) in the transverse direction T (e.g., as shown in FIGS. 4 and 6)

The second printed circuit board 292 may be supported by (e.g., attached to) carrier 250 at the rear surface 253 of the carrier 250. For example, the second printed circuit board 292 may be received in a recess 265 formed in the rear surface 253 of the carrier 250 (e.g., as shown in FIGS. 4-6). The recess 265 may have an interior surface 267 in which a window 266 (e.g., an opening) is formed (e.g., such that the interior surface 267 surrounds the window 266). The window may extend through the carrier 250 from the front surface 251 to the interior surface 267 of the carrier 250 within the recess 265. When the second printed circuit board 292 is received in the recess 265 of the carrier 250, the environmental sensing circuit 294 may be received in the window 266 (e.g., an opening) in the carrier 250. When the second printed circuit board 292 is attached to the carrier 250 within the recess 265, the front surface 291 of the second printed circuit board 292 may contact the interior surface 267 of the carrier 250 within the recess 265 (e.g., as shown in FIG. 6). In this configuration, the environmental sensing circuit 294 may be configured to receive air from outside of the control device 200 via the cavity 245 in the bezel 210 (e.g., and via the apertures 242 of the ventilation portion 240). The rear surface 213 of the body 212 of the bezel 210 around the opening 241 of the cavity 245 may surround the window 266 in the carrier 250. In some examples, the rear surface 213 of the body 212 of the bezel 210 surrounding the opening 241 of the cavity 245 may contact the front surface 251 of the carrier 250 surrounding the window 266 in the carrier 250. In this fashion, the opening 241 of the cavity 245 in rear surface 213 of the bezel 210 may be sealed by a combination of the front surface 251 of the carrier 250 and the front surface 291 of the second printed circuit board 292.

In addition, the photosensing circuit 296 may also be received in the window 266 in the carrier 250 and may be located above the environmental sensing circuit 294 on the second printed circuit board 272 (e.g., as shown in FIG. 4). The photosensing circuit 296 may be configured to receive light from outside the control device 200 via one or more of the apertures 242 of the ventilation portion 240. In one example, light may enter the cavity 245 via all of the apertures 242 of the ventilation portion 240. However, by being situated above the environmental sensing circuit 294, the photosensing circuit 296 may only detect light entering the cavity 245 via a subset (e.g., less than all) of the apertures 242 of the ventilation portion 240.

As shown in FIG. 8, the carrier 250 may comprise posts, such as a first unformed stake 268 and a second unformed stake 269, which both may extend from the interior surface 267 of the carrier 250 within the recess 265. When the second printed circuit board 292 is received in the recess 265 of the carrier 250, the first and second unformed stakes 268, 269 may be received through respective openings 298, 299 in the second printed circuit board 292. The first and second unformed stakes 268, 269 may be formed (e.g., heated and/or melted as part of a heat-staking process) to produce formed stakes 268′, 269′ (e.g., as shown in FIGS. 4-6) for securing the second printed circuit board 272 to the interior surface 267 of the carrier 250 within the recess 265. As shown in FIGS. 7 and 8, the opening 299 in the second printed circuit board may be partially open on one end of the second printed circuit board 292 (e.g., the opening 299 may be a slot in the second printed circuit board 292). The second printed circuit board 292 may be attached to the carrier 250 within the recess 265 such that the interior surface 267 of the carrier 250 around the window 266 contacts (e.g., make a firm connection with) the front surface 291 of the second printed circuit board 292.

When the second printed circuit board 292 is received in the recess 265 of the carrier 250 (e.g., as shown in FIG. 6), the second printed circuit board 292 may be located at least partially outside of the bezel 210 (e.g., outside the area A_{BEZEL} of the bezel 210). The window 266 in the carrier 250 may extend (e.g., in the lateral direction A) past the right side edge 218 of the bezel 210 (e.g., as shown in FIG. 6). When the bezel 210 is attached to the carrier 250, the cross-sectional area of the cavity 245 (e.g., in a plane that extends in the longitudinal direction L and the lateral direction A) at least partially overlaps a cross-sectional area of the window 266 (in the carrier 250 (e.g., in a plane that extends in the longitudinal direction L and the lateral direction A). The environmental sensing circuit 294 may be mounted to the second printed circuit board 292 and received in the window 266 in the carrier 250, such that the environmental sensing circuit 294 is located at least partially behind the outer wall 246 of the body 212 of the bezel 210. A center of the environmental sensing circuit 294 may not be aligned with a center of the cavity 245 (e.g., as can be seen in FIG. 6).

As shown in FIGS. 6 and 8, the outer wall 246 of the body 212 of the bezel 210 that lies between the right side edge 218 of the bezel 210 and the cavity 245 may comprise a notch 238 (e.g., a channel) extending from the interior surface 243 of the bezel 210 within the cavity 245 (e.g., in the transverse direction T) towards the environmental sensing circuit 294 mounted to the second printed circuit board 292 (e.g., the notch 238 may be located adjacent to the location of the environmental sensing circuit 294). The notch 238 may comprise an angled edge 239 near the rear surface 213 of the body 212 of the bezel 210 (e.g., near the environmental sensing circuit 294). The angled edge 239 may increase the exposure of the environmental sensing circuit 294 to the air within the cavity 245. The outer wall 246 may extend from the interior surface 243 of the bezel 210 within the cavity 245 to the front surface 251 of the carrier 250, such that the rear surface 213 of the body 212 of the bezel 210 contacts the front surface 251 of the carrier 250 behind the outer wall 246 (e.g., behind the flange portion 241). In addition, the inner wall 247 may extend from the interior surface 243 of the bezel 210 within the cavity 245 to the front surface 251 of the carrier 250, such that the rear surface 213 of the bezel 210 contacts the front surface 251 of the carrier 250 behind the inner wall 247. In addition, the end walls 248 of the body 212 of the bezel 210 (e.g., that extend between the outer wall 246 and the inner wall 247) also contact the front surface 251 of the carrier 250.

The bezel 210, the carrier 250, and the second printed circuit board 272 may form a second volume within the control device 200 in which the environmental sensing circuit 294 is located. For example, the cavity 245 in the bezel 210 (e.g., the interior surface 243, the outer wall 246, the inner wall 247, and the end walls 248), the window 266 in the carrier 250, and the second printed circuit board 272 may form a second volume within the control device 200 in which the environmental sensing circuit 294 is located. The second volume formed by the cavity 245, the window 266, and the second printed circuit board 272 may be open (e.g., substantially only open) to the air from outside of the control device (e.g., from outside of the second volume) via the apertures 242 of the ventilation portion 240. For example, the second volume formed by the cavity 245, the window 266, and the second printed circuit board 272 may be separate (e.g., sealed from) the first volume formed between the enclosure 280 and the carrier 250.

While the control device 200 shown in FIGS. 2-8 has been described with the control actuator 220 operating as a pushbutton, the control device 200 could comprise other types and/or numbers of actuators received in the opening 214 of the bezel 210. For example, the control device 200 may two pushbutton actuators received in the opening 214 of the bezel 210, where an upper one of the pushbutton actuators may be actuated to cause the control device 200 to turn on the exhaust fan and a lower one of the pushbutton actuators may be actuated to cause the control device 200 to turn off the exhaust fan. In addition, the control device 200 may comprise a paddle actuator configured to pivot about a central axis within the opening of the bezel 210, where the paddle actuator has an upper portion that may be actuated to cause the control device 200 to turn on the exhaust fan and a lower portion that may be actuated to cause the control device 200 to turn off the exhaust fan.

While the control device 200 shown in FIGS. 2-8 has been described with the ventilation portion 240 located on the second side portion 216 (e.g., the right side portion between the opening 214 and the right side edge 218 of the bezel 210), the ventilation portion 240 could be located on the first side portion 215 (e.g., the left side portion between the opening 214 and the left side edge 217 of the bezel 210). In such an example, the second printed circuit board 292 may be located within the control device 200 behind the first side portion 215 of the bezel 210. In addition, the control device 200 could comprise two ventilation portions with a first one of the ventilation portions located on the first side portion 215 (e.g., the left side portion between the opening 214 and the left side edge 217 of the bezel 210) and a second one of the ventilation portions located on the second side portion 216 (e.g., the right side portion between the opening 214 and the right side edge 218 of the bezel 210). In such an example, the photosensing circuit 296 may be located behind the first side portion 215 and the environmental sensing circuit 294 may be located behind the second side portion 216 (e.g., and vice versa).

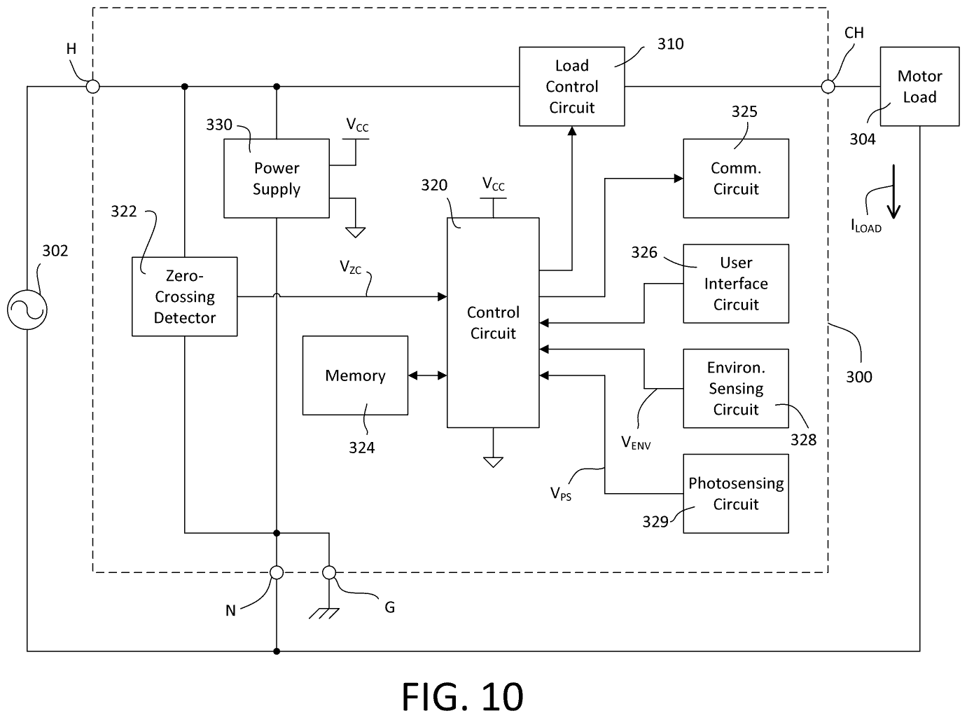

FIG. 10 is a simplified block diagram of an example of a load control device 300 that may be deployed as, for example, the motor control device 120 of the load control system 100 shown in FIG. 1 and/or the control device 200 shown in FIGS. 2-9. The load control device 300 may be adapted to be coupled in series electrical connection between a power source 302, such as an alternating-current (AC) power source, and an electrical load, such as a motor load 304 (e.g., an exhaust fan, such as the exhaust fan 104 shown in FIG. 1). The load control device 300 may include a hot terminal H that may be adapted to be coupled to a hot side of the power source 302 and a controlled-hot terminal CH that may be adapted to be coupled to the motor load 304. In some examples, the load control device 300 may also comprise a neutral terminal N that may be adapted to be coupled to a neutral side of the power source 302. In addition, the load control device 300 may comprise a ground terminal G that may be adapted to be coupled to earth ground. In some examples, the power source 302 may comprise a direct-current (DC) power source.

The load control device 300 may comprise a load control circuit 310 (e.g., a motor control circuit) coupled in series electrical connection between the hot terminal H and the controlled-hot terminal CH and thus coupled in series electrical connection between the power source 302 and the motor load 304. The load control circuit 310 may be configured to control power delivered to the motor load 304. For example, the load control circuit 310 may comprise a switching circuit, such as a relay, for connecting the motor load 304 to and disconnecting the motor load 304 from the power source 302 to turn the motor load 304 on and off, respectively. The load control device 300 may comprise a control circuit 320 (e.g., the processor 274) configured to control the load control circuit 310 (e.g., the relay of the load control circuit 310) to control the power delivered to the motor load 304, for example, to turn the motor load 304 on and off. The control circuit 320 may include one or more of a processor (e.g., a microprocessor), a microcontroller, a programmable logic device (PLD), a field programmable gate array (FPGA), an application specific integrated circuit (ASIC), or any suitable controller or processing device. For example, the control circuit 320 may be configured to render the relay of the load control circuit 310 conductive and non-conductive to turn the motor load 304 on and off, respectively.

The load control device 300 may comprise a power supply 330. The power supply 330 may generate a direct-current (DC) supply voltage V_{CC} for powering the control circuit 320 and the other low-voltage circuitry of the load control device 300. The power supply 330 may be coupled between the hot terminal H and the neutral terminal N (e.g., across the power source 302). In addition, the power supply 330 may also be coupled between the hot terminal H and the ground terminal G (e.g., between the hot terminal H and earth ground when a connection to the neutral side of the power source 302 is not available). The power supply 330 may be configured to conduct a charging current from the power source 302 to generate the DC supply voltage V_{CC}.

The load control device 300 may comprise a zero-crossing detector 322 (e.g., a zero-cross detect circuit) electrically coupled between the hot terminal H and the neutral terminal N (e.g., across the power source 302). In addition, the zero-crossing detector 322 may also be coupled between the hot terminal H and the ground terminal G (e.g., between the hot terminal H and earth ground when a connection to the neutral side of the power source 302 is not available). The zero-crossing detector 322 may be configured to generate a zero-cross detect signal V_{ZC} that indicates the zero-crossing points of an AC mains line voltage generated by the power source 302. The control circuit 320 may receive the zero-cross detect signal V_{ZC} and may be configured to render the relay of the load control circuit 310 conductive and non-conductive based on the zero-cross detect signal V_{ZC}. For example, the control circuit 320 may be configured to render the relay of the load control circuit 310 conductive and non-conductive at approximately the zero-crossings of the AC mains line voltage as determined from the zero-cross detect signal V_{ZC} received from the zero-crossing detector 322.

The load control device 300 may comprise a memory 324 that may be communicatively coupled to the control circuit 320 for the storage and/or retrieval of data. The memory 324 may be implemented as an external integrated circuit (IC) or as an internal circuit of the control circuit 320. The memory 324 may comprise a computer-readable storage media or machine-readable storage media that maintains computer-executable instructions for performing one or more procedure and/or functions as described herein. For example, the memory 324 may comprise computer-executable instructions or machine-readable instructions that when executed by the control circuit 320 configure the control circuit 320 to provide one or more portions of the procedures described herein. The control circuit 320 may access the instructions from the memory 324 for being executed to cause the control circuit 320 to operate as described herein, or to operate one or more other devices as described herein. The memory 324 may comprise computer-executable instructions for executing configuration software. For example, the control circuit 320 may be configured to store in and retrieve from the memory 324 configuration data for configuring the load control device 300. In addition, the control circuit 320 may be configured to store in and retrieve from the memory 324 configuration settings and/or operational settings (e.g., such as an operating mode, a humidity sensitivity level, a timeout period T_{TIME-OUT}, etc.). For example, the operational characteristics stored in the memory 324 may be configured during a configuration procedure of the load control device 300.

The load control device 300 may comprise a communication circuit 325 configured to communicate (e.g., transmit and/or receive) messages (e.g., digital messages). For example, the communication circuit 325 may comprise one or more wired communication circuits and/or wireless communication circuits. The one or more wired communication circuits and/or wireless communication circuits of the communication circuit 325 may be implemented as external integrated circuits (ICs) or as internal circuits of the control circuit 320. For example, the one or more wireless communication circuits of the communication circuit 325 may include for example, one or more a radio-frequency (RF) transceivers coupled to a respective antenna for transmitting and/or receiving RF signals. In addition, the one or more wireless communication circuits of the communication circuit 325 may also include an RF transmitter for transmitting RF signals, an RF receiver for receiving RF signals, or an infrared (IR) transmitter and/or receiver for transmitting and/or receiving IR signals. The one or more wireless communication circuits of the communication circuit 325 may be capable of performing communication via the same communication channels or different communication channels. In some examples, the communication circuit 325 may be configured to communicate via a network, such as a wireless or wired local area network (LAN), e.g., for access to the Internet. In addition, the communication circuit 325 may be configured to communicate via a control network (e.g., a wired or wireless control communication link). The control circuit 320 may be configured to receive messages including control data (e.g., one or more commands) for controlling the motor load 304 via the communication circuit 325. In addition, the control circuit 320 may be configured to transmit messages (e.g., including feedback data, such as status information of the load control device 300) via the communication circuit 325.

The load control device 300 may further comprise a user interface circuit 326. The user interface circuit 326 may comprise one or more input circuits for receiving inputs (e.g., user inputs). For example, the input circuits of the user interface circuit 326 may comprise one or more switches (e.g., such as the tactile switches 277, 278 of the control device 200) configured to be actuated in response to actuation of one or more respective actuators (e.g., buttons) of the load control device 300 (e.g., the control actuator 124 of the motor control device 120, the control actuator 220 of the control device 200, and/or the programming actuators 260 of the control device 200). The control circuit 320 may be configured to generate control data (e.g., one or more commands) for controlling the motor load 304 in response to the user inputs received via the user interface circuit 326 (e.g., in response to actuations of the switches of the user interface circuit 326). For example, the control circuit 320 may be configured to control the relay of the load control circuit 310 to turn the motor load 304 on and off in response to the user inputs received via the user interface circuit 326. In addition, the control circuit 320 may be configured to configure the control device 300 (e.g., by adjusting the configuration settings and/or operational settings stored in the memory 324) in response to the user inputs received via the user interface circuit 326 (e.g., as will be described in greater detail below).

The user interface circuit 326 may also comprise one or more light sources configured to illuminate one or more visible indicators of the load control device 300 (e.g., such as the visible indicator 230 of the control device 200) for providing feedback information to a user. For example, the one or more light sources of the user interface circuit 326 may comprise light-emitting diodes (e.g., such as the light-emitting diodes 279 of the control device 200). The control circuit 320 may be configured to control one of light sources of the user interface circuit 326 to illuminate the visible indicator a first color (e.g., white) and to control another one of the light sources of the user interface circuit 326 to illuminate the visible indicator a second color (e.g., blue). For example, the control circuit 320 may be configured to control the light-emitting diodes of the user interface circuit 326 to illuminate the visible indicator to the first color (e.g., white) when the control circuit 320 has turned on the motor load 304 in response to an actuation of one of the switches of the user interface circuit 326.

The load control device 300 may further comprise an environmental sensing circuit 328 (e.g., such as the environmental sensing circuit 294 of the control device 200). The environmental sensing circuit 328 may comprise, for example, a humidity sensing circuit and/or a temperature sensing circuit. For example, the environmental sensing circuit 328 may comprise one or more integrated circuits (ICs) mounted to a printed circuit board inside the control device 300 (e.g., such as the second printed circuit board 292 of the control device 200). The environmental sensing circuit 328 may be configured to sense one or more environmental characteristics (e.g., a humidity level and/or an ambient temperature) in the space in which the control device 300 is located and/or installed. The control device 300 may comprise a ventilation portion (e.g., such as the ventilation portion 240 of the bezel 210) for allowing air from outside of the control device 300 (e.g., from the space around the control device 300) to enter control device 300 to be measured by the environmental sensing circuit 328. The environmental sensing circuit 328 may be configured to generate one or more sense signals V_{ENV} that are representative of the respective sensed environmental characteristics.

The control circuit 320 may be configured to receive the one or more sense signals V_{ENV} generated by the environmental sensing circuit 328. In some examples, the environmental sensing circuit 328 may be configured to transmit one or more messages (e.g., digital messages) including indications of the sensed environmental characteristics to the control circuit 320 (e.g., via a communication bus, such as an I²C communication bus). For example, the control circuit 320 may be configured to determine a humidity level L_{HUM} in in the space in which the control device 300 is located and/or installed in response to the one or more sense signals V_{ENV} generated by the environmental sensing circuit 328.

The control circuit 320 may be configured to generate control data (e.g., one or more commands) for controlling the motor load 304 in response to the one or more sense signals V_{ENV} generated by the environmental sensing circuit 328. For example, the control circuit 320 may be configured to control (e.g., automatically control) the relay of the load control circuit 310 to turn the motor load 304 (e.g., an exhaust fan) on and off to control the humidity level L_{HUM} in the space around the control device 200. In some examples, the control circuit 320 may be configured to turn on the motor load 304 when the humidity level L_{HUM} (e.g., as indicated by the one or more sense signals V_{ENV}) exceeds a first threshold humidity L_{TH-H1} (e.g., a turn-on threshold humidity). The control circuit 320 may be configured to control the light-emitting diodes of the user interface circuit 326 to illuminate the visible indicator of the control device 300 to the second color (e.g., blue) when the control circuit 320 has turned on (e.g., automatically turned on) the motor load 304 in response to the one or more sense signals V_{ENV}. The control circuit 320 may be configured to turn off the motor load 304 when the humidity level L_{HUM} (e.g., as indicated by the one or more sense signals V_{ENV}) drops below a second threshold humidity L_{TH-H2} (e.g., a turn-off threshold humidity), which may be less than the first threshold humidity level L_{TH-H1}. In addition, the control circuit 320 may be configured to turn off the motor load 304 after a timeout period T_{TIME-OUT} from when the control circuit 320 turned on (e.g., automatically turned on) the motor load 304 in response to the humidity level L_{HUM} (e.g., as indicated by the one or more sense signals V_{ENV}). In some examples, the control circuit 320 may be configured to transmit, via the communication circuit 325, one or more messages including the control data for controlling the motor load 304 in response to the one or more sense signals V_{ENV} generated by the environmental sensing circuit 328.

The load control device 300 may further comprise a photosensing circuit 329 (e.g., such as the photosensing circuit 296 of the control device 200). For example, the photosensing circuit 329 may comprise one or more integrated circuits (ICs) mounted to a printed circuit board inside the control device 300 (e.g., such as the second printed circuit board 292 of the control device 200). The photosensing circuit 329 may be configured to sense (e.g., measure) a light level L_{PS} (e.g., an ambient light level) in the space in which the control device 300 is located and/or installed. The photosensing circuit 329 may be configured to generate a sense signal V_{PS} that indicates and/or is representative of the light level L_{PS} in the space in which the control device 300 is located and/or installed (e.g., as measured by the photosensing circuit 296). The photosensing circuit 329 may be configured to receive light from outside of the control device 300 (e.g., via one or more of the apertures 242 of the ventilation portion 240 of the control device 200).

The control circuit 320 may be configured to receive the sense signal V_{PS} generated by the photosensing circuit 329. For example, the control circuit 320 may be configured to sample and process the sense signal V_{PS} generated by the photosensing circuit 329 to determine when the light level L_{PS} in the space in which the control device 200 is located and/or installed exceeds a light threshold L_{TH}, for example, to determine when a lighting load that is also installed in the space (e.g., the lighting load 102 controlled by the lighting control device 110) is turned on (e.g., which may provide an indication of when the space is occupied). The control circuit 320 may be configured to generate control data (e.g., one or more commands) for controlling the motor load 304 in response to the sense signal V_{PS} generated by the photosensing circuit 329. The control circuit 320 may be configured to control the load control circuit 310 to turn on (e.g., only automatically turn on) the motor load 304 in response to the one or more sense signals V_{ENV} generated by the environmental sensing circuit 328 when the sense signal V_{PS} received from the photosensing circuit 329 indicates that the space is occupied (e.g., when the light level L_{PS} exceeds the light threshold L_{TH}). For example, the control circuit 320 may be configured to control the relay of the load control circuit 310 to turn on the motor load 304 when the humidity level L_{HUM} (e.g., as indicated by the one or more sense signals V_{ENV}) exceeds the first threshold humidity _{LTH-H1} and the light level L_{PS} exceeds the light threshold L_{TH}). The control circuit 320 may be configured to determine when the turn off the motor load 304 independent of the sense signal V_{PS} received from the photosensing circuit 329. In some example, the load control device 300 may comprise an occupancy sensing circuit, such as a passive-infrared sensing circuit, for determining if the space is occupied (e.g., in place of or in addition to the photosensing circuit 329).

The control circuit 320 may be configured to operate in one or more different operating modes, such as a humidity-control mode, an air-cycle mode, and a manual mode. When in the humidity-control mode, the control circuit 320 may be configured to control (e.g., automatically control) the motor load 304 in response to the one or more sense signals V_{ENV} generated by the environmental sensing circuit 328. For example, when in the humidity-control mode, the control circuit 320 may be configured to turn on the motor load 304 when the humidity level L_{HUM} exceeds the first threshold humidity L_{TH-H1}, and to turn off the motor load 304 when the humidity level L_{HUM} drops below the second threshold humidity L_{TH-H2} or after the timeout period T_{TIME-OUT} from when the control circuit 320 turned on the motor load 304 in response to the one or more sense signals V_{ENV}. When in the air-cycle mode, the control circuit 320 may be configured to periodically control the motor load 304 (e.g., according to a time schedule). For example, when in the air-cycle mode, the control circuit 320 may be configured to turn on the motor load 304 for an air-cycle period T_{AIR-CYCLE} (e.g., approximately 15 minutes) each hour. When in the manual mode, the control circuit 320 may be configured to turn on (e.g., only turn on) the motor load 304 in response to an actuation of one of the switches of the user interface circuit 326, for example, when one of the actuators of the load control device 300 (e.g., the control actuator 124 of the motor control device 100 and/or the control actuator 220 of the control device 200) is actuated. In addition, when in the manual mode, the control circuit 320 may be configured to turn off the motor load 304 in response to an actuation of one of the switches of the user interface circuit 326 when the motor load 304 is on or after the timeout period T_{TIME-OUT} from when the control circuit 320 turned on the motor load 304 in response to an actuation of one of the switches of the user interface circuit 326. The control circuit 320 may not be configured to control (e.g., automatically control) the motor load 304 in response to the one or more sense signals V_{ENV} generated by the environmental sensing circuit 328 when in the air-cycle mode or the manual mode.

The control circuit 320 may be configured to configure the operation of the control device 300 in response to actuations of the switches of the user interface circuit 326, for example, when the actuators of the load control device 300 (e.g., one of the programming actuators 260 of the control device 200) is actuated. The control circuit 320 may be configured to adjust the configuration settings and/or operational settings stored in the memory 324 in response to actuations of the switches of the user interface circuit 326. For example, the control circuit 320 may be configured to select one of the operating modes (e.g., the humidity-control mode, the air-cycle mode, and/or the manual mode) in which to operate in response to actuations of the switches of the user interface circuit 326. In addition, the control circuit 320 may be configured to set the humidity sensitivity level (e.g., as stored in the memory 324) to one of multiple levels (e.g., a low level, a medium level, and/or a high level) in response to actuations of the switches of the user interface circuit 326. For example, the control circuit 320 may be configured to set the first threshold humidity L_{TH-H1} and/or the second threshold humidity L_{TH-H2} (e.g., to be used when operating in the humidity-control mode) based on the humidity sensitivity level that is set (e.g., one of the low level, the medium level, or the high level). Further, the control circuit 320 may be configured to set the timeout period T_{TIMEOUT} (e.g., as stored in the memory 324) in response to actuations of the switches of the user interface circuit 326. In some examples, the control circuit 320 may be configured to set the air-cycle period T_{AIR-CYCLE} (e.g., for use in the air-cycle mode) in response to actuations of the switches of the user interface circuit 326.

Although features and elements are described herein in particular combinations, each feature or element can be used alone or in any combination with the other features and elements. The methods described herein may be implemented in a computer program, software, instructions, or firmware stored on one or more non-transitory computer-readable media or other machine-readable media for execution by a computer or machine, or portion thereof. For example, the computer-readable or machine-readable media may be executed by a control circuit, such as a processor. Examples of computer-readable media or machine-readable media include electronic signals (transmitted over wired or wireless connections) and computer-readable storage media. Examples of computer-readable storage media include, but are not limited to, a read only memory (ROM), a random access memory (RAM), removable disks, and optical media such as CD-ROM disks, and digital versatile disks (DVDs). The control circuit may access the computer program, software, instructions, or firmware stored on the computer-readable media or machine-readable media for being executed to cause the control circuit to operate as described herein, or to operate one or more devices as described herein.

1. A control device for controlling an electrical load, the control device comprising:
a bezel comprising an opening in a front surface of the bezel;
a control actuator received in the opening in the front surface of the bezel, the front surface of the bezel comprising a first side portion on a left side of the control actuator and a second side portion on a right side of the control actuator;
an environmental sensing circuit configured to sense an environmental characteristic in a space around the control device; and
a control circuit configured to control the electrical load in response to actuations of the control actuator and in response to the environmental sensing circuit;
wherein the bezel comprises a ventilation portion on at least one of the left side portion or the right side portion of the front surface of the bezel, the ventilation portion comprising a plurality of apertures extending through the bezel from the front surface of the bezel to an interior surface of the bezel, the interior surface being opposite the front surface of the bezel, the bezel further defining a cavity located proximate the ventilation portion, the interior surface of the bezel defining at least a portion of a boundary of the cavity, the environmental sensing circuit configured to receive air from outside of the bezel via the ventilation portion and the cavity in the bezel.

2. The control device of claim 1, further comprising:
a carrier to which the bezel is attached, the carrier configured to be mounted to an electrical wallbox;
a first printed circuit board to which the control circuit is mounted, the first printed circuit board supported by the carrier.

3. The control device of claim 2, further comprising:
a second printed circuit board to which the environmental sensing circuit is mounted, the second printed circuit board located within the control device such that the environmental sensing circuit is located behind the ventilation portion of the bezel and is directed towards the cavity of the bezel;
wherein the second printed circuit board is electrically coupled to the first printed circuit board, such that the control circuit is responsive to the environmental sensing circuit.

4. The control device of claim 3, wherein the second printed circuit board is mounted at a rear surface of the carrier and the environmental sensing circuit is received in a window in the carrier that extends through the carrier such that the environmental sensing circuit configured to receive air from outside of the bezel via the ventilation portion and the cavity.

5. The control device of claim 4, wherein the cavity in the bezel comprises an opening at a rear surface of the bezel, and the rear surface of the bezel around the opening of the cavity surrounds the window in the carrier, such the cavity in the bezel, the window in the carrier, and the second printed circuit board form a volume in which the environmental sensing circuit is located.

6. The control device of claim 5, wherein the bezel defines an outer wall between the cavity and an edge of the bezel, the outer wall extending from the interior surface of the bezel within the cavity to the front surface of the carrier.

7. The control device of claim 6, wherein the environmental sensing circuit is located at least partially behind the outer wall of the bezel.

8. The control device of claim 7, wherein the outer wall of the bezel defines a notch extending from the interior surface of the bezel towards the environmental sensing circuit.

9. The control device of claim 8, wherein the notch in the outer wall defines an angled edge near the rear surface of the body of the bezel to increase exposure of the environmental sensing circuit to air within the cavity.

10. The control device of claim 9, wherein the bezel defines an inner wall between the cavity and the opening in the bezel in which the control actuator is located, the inner wall extending from the interior surface of the bezel within the cavity to the front surface of the carrier.

11. The control device of claim 5, wherein the rear surface of the bezel surrounding the opening of the cavity contacts the front surface of the carrier surrounding the opening in the carrier.

12. The control device of claim 4, wherein the second printed circuit board is received in a recess in the rear surface of the carrier.

13. The control device of claim 12, wherein the window in the carrier is located within the recess and extends from a front surface of the carrier to an interior opposing surface of the carrier, such that the interior surface of the carrier surrounds the window.

14. The control device of claim 13, wherein the second printed circuit board is attached to the carrier within the recess such that the interior surface of the carrier surrounding the window contacts a front surface of the second printed circuit board.

15. The control device of claim 14, wherein the carrier comprises a stake extending from the interior surface of the carrier within the recess and received through an opening in the second printed circuit board, the stake configured to be formed through a heat-staking process to attach the second printed circuit board to the carrier.

16. The control device of claim 4, wherein a cross-sectional area of the cavity of the bezel at least partially overlaps a cross-sectional area of the window in the carrier.

17. The control device of claim 2, wherein the control actuator is substantially centered on the front surface of the bezel.

18. The control device of claim 17, wherein the control actuator bisects the front surface of the bezel, such that the first and second side portions of the front surface of the bezel have equal widths, and wherein the bezel is sized to be received in an opening of a designer-style faceplate.

19. The control device of claim 17, wherein the control actuator extends for more than 90% of a length of the bezel.

20. The control device of claim 17, wherein the control actuator occupies approximately two-thirds of the front surface of the bezel.

21. The control device of claim 3, further comprising:
a photosensing circuit mounted to the second printed circuit board, the photosening circuit configured to receive light from outside of the control device via at least one of the apertures of the ventilation portion of the bezel, and to generate a control signal that indicates a light level outside of the control device;
wherein the control circuit is further configured to control the electrical load in response to the control signal generated by the photosensing circuit.

22. The control device of claim 2, wherein the carrier comprises a yoke portion and side walls extending from the yoke portion to form a cavity in which the first printed circuit board is received.

23. The control device of claim 22, wherein the yoke portion of the carrier comprises holes configured to receive respective fasteners for mounting the carrier to the electrical wallbox.

24. The control device of claim 22, wherein the carrier comprises clips extending from a rear surface of the yoke portion for attaching the first printed circuit board to the carrier.

25. The control device of claim 22, further comprising:
an enclosure connected to the carrier, such that the first printed circuit board is housed between the carrier and the enclosure.

26. The control device of claim 2, wherein the ventilation portion is located on the right side portion of the front surface of the bezel, and the control device further comprises:
a visual indicator located on the left side portion of the front surface of the bezel; and
a light source mounted to the first printed circuit board and configured to illuminate the visual indicator on the front surface of the bezel;
where the control circuit is configured to control the light source to illuminate the visual indicator to indicate at least one of a status of the electrical load or a mode of the control device.

27. The control device of claim 2, further comprising:
a load control circuit mounted to the first printed circuit board, the load control circuit configured to be electrically connected between a power source and the electrical load for controlling power delivered to the electrical load;
wherein the control circuit is configured to control the load control circuit to control the electrical load in response to actuations of the control actuator and in response to the environmental sensing circuit.

28. The control device of claim 2, further comprising:
a communication circuit mounted to the first printed circuit board;
wherein the control circuit is configured to transmit, via the communication circuit, one or more messages for controlling the electrical load in response to actuations of the control actuator and in response to the environmental sensing circuit.

29. The control device of claim 1, wherein the electrical load comprises a fan and the environmental sensing circuit comprises a humidity sensor circuit, the control circuit configured to control the fan in response to the humidity sensor circuit in order to control a humidity level in the space in which the control device is located.

30. The control device of claim 1, wherein the bezel is configured to be received within an opening of a faceplate when the faceplate is mounted to the control device.

31-90. (canceled)
